(19) United States
(12) Patent Application Publication
(10) Pub. No.: US 2025/0140678 A1
(43) Pub. Date: May 1, 2025

(54) SUBSTRATE AND SEMICONDUCTOR MODULE INCLUDING THE SAME

(71) Applicant: SAMSUNG ELECTRONICS CO., LTD., SUWON-SI (KR)

(72) Inventors: Jihyun LEE, Suwon-si (KR); Insik HAN, Suwon-si (KR)

(21) Appl. No.: 18/783,847

(22) Filed: Jul. 25, 2024

(30) Foreign Application Priority Data
Nov. 1, 2023 (KR) 10-2023-0149282

(51) Int. Cl. H01L 23/498; H01L 21/48; H01L 23/00; H01L 23/31

(52) U.S. Cl. CPC H01L 23/49838; H01L 21/4857; H01L 23/49822; H01L 23/3107; H01L 23/49816; H01L 24/16; H01L 2224/16227

(57) ABSTRACT

A substrate includes a base substrate comprising a center region and a corner region in a plan view. The base substrate comprises wiring patterns and an insulating layer. First conductive pads are on an upper surface of the center region of the base substrate. Second conductive pads are on an upper surface of the corner region of the base substrate. Each of the first conductive pads has a circular or oval shape in the plan view. Each of the second conductive pads has a polygonal shape in the plan view.

### CROSS-REFERENCE TO RELATED APPLICATION

This application claims priority under 35 U.S.C. § 119 to Korean Patent Application No. 10-2023-0149282, filed on Nov. 1, 2023 in the Korean Intellectual Property Office, the disclosure of which is incorporated by reference in its entirety herein.

### 1. TECHNICAL FIELD

The present inventive concept relates to a substrate, and more particularly, to a substrate used in a semiconductor module.

### 2. DISCUSSION OF RELATED ART

There has been an increased demand for weight reduction and miniaturization of electronic devices, such as mobile phones and laptops. Therefore, there has been an increased demand for miniaturization of semiconductor modules used in electronic devices. A semiconductor module may include a board substrate and a semiconductor package mounted on the board substrate. For example, a semiconductor package may be mounted on a board substrate by using solder balls. However, the difficulty of a process of mounting the semiconductor package increases as the miniaturization of the semiconductor modules increases.

### SUMMARY

Embodiments of the present disclosure provides a semiconductor module with increased reliability and a substrate used in manufacturing the semiconductor module.

Embodiments of the present disclosure also provides a semiconductor module manufactured with increased yield and a substrate used in manufacturing the semiconductor module.

Embodiments of the present disclosure relates to a substrate and a semiconductor module including the substrate.

According to an embodiment of the present disclosure, a substrate includes a base substrate comprising a center region and a corner region in a plan view. The base substrate comprises wiring patterns and an insulating layer. First conductive pads are on an upper surface of the center region of the base substrate. Second conductive pads are on an upper surface of the corner region of the base substrate. Each of the first conductive pads has a circular or oval shape in the plan view. Each of the second conductive pads has a polygonal shape in the plan view.

According to an embodiment of the present disclosure, a substrate includes a base substrate comprising a center region and a corner region in a plan view. First conductive pads are on an upper surface of the center region of the base substrate. Second conductive pads are on an upper surface of the corner region of the base substrate. Each of the second conductive pads has a polygonal shape in the plan view. Each of the first conductive pads has a different shape in the plan view than the polygonal shape of the second conductive pads in the plan view. The second conductive pads are arranged in rows extending in a first direction in the plan view. A number of the second conductive pads in an (a+1) row is less than a number of the second conductive pads in a first row. (a) is a natural number greater than or equal to 1. The second conductive pads in the first row are disposed between a first side surface of the base substrate and the second conductive pads in the (a+1) row.

According to an embodiment of the present disclosure, a semiconductor module includes a module substrate. A semiconductor package is disposed on an upper surface of the module substrate. The module substrate comprises a base substrate comprising a center region and corner regions in a plan view. The base substrate comprising wiring patterns and an insulating layer. Conductive pads are disposed on an upper surface of the base substrate. The conductive pads are electrically connected to the wiring patterns. Each of the conductive pads comprises a seed pattern and a metal pad on the seed pattern. The seed pattern is disposed between the metal pad and a corresponding one of the wiring patterns. The conductive pads comprise first conductive pads disposed on an upper surface of the center region of the base substrate. Each of the first conductive pads has a circular or oval shape in the plan view. Second conductive pads are disposed on upper surfaces of the corner regions of the base substrate. Each of the second conductive pads has a polygonal shape in the plan view. The semiconductor package comprises a package substrate. A semiconductor chip is mounted on an upper surface of the package substrate. A molding layer is disposed on the upper surface of the package substrate. The molding layer covers the semiconductor chip. Solder balls are disposed on a lower surface of the package substrate. The solder balls are connected to the conductive pads.

### BRIEF DESCRIPTION OF THE DRAWINGS

Embodiments of the present disclosure will be more clearly understood from the following detailed description taken in conjunction with the accompanying drawings in which:

FIG. 1 is a plan view showing a circuit substrate according to an embodiment of the present disclosure;

FIG. 2A is a plan view for explaining a substrate according to an embodiment of the present disclosure;

FIG. 2B is an enlarged view of region I of FIG. 2A according to an embodiment of the present disclosure;

FIG. 2C is a cross-section taken along line II-II′ of FIG. 2A according to an embodiment of the present disclosure;

FIG. 2D is an enlarged view of region III of FIG. 2C according to an embodiment of the present disclosure;

FIG. 3A is a plan view for explaining a substrate according to an embodiment of the present disclosure;

FIG. 3B is an enlarged view of region I of FIG. 3A according to an embodiment of the present disclosure;

FIG. 4A is a plan view illustrating a substrate according to an embodiment of the present disclosure;

FIG. 4B is an enlarged view of region I of the substrate of FIG. 4A according to an embodiment of the present disclosure;

FIG. 5A is a plan view illustrating a substrate according to an embodiment of the present disclosure;

FIG. 5B is a plan view illustrating a substrate according to an embodiment of the present disclosure;

FIG. 5C is a plan view illustrating a substrate according to an embodiment of the present disclosure;

FIG. 6A is a cross-sectional view showing a semiconductor module according to an embodiment of the present disclosure;

FIG. 6B is a cross-sectional view showing a semiconductor module during a reflow process according to an embodiment of the present disclosure; and

FIGS. 7A to 7G are diagrams illustrating a method of manufacturing a substrate according to some embodiments of the present disclosure.

### DETAILED DESCRIPTION OF EMBODIMENTS

In the specification, the same reference numerals may refer to the same elements throughout. Hereinafter, a substrate, a method of manufacturing a substrate, and a semiconductor module according to non-limiting embodiments of the present disclosure will be described.

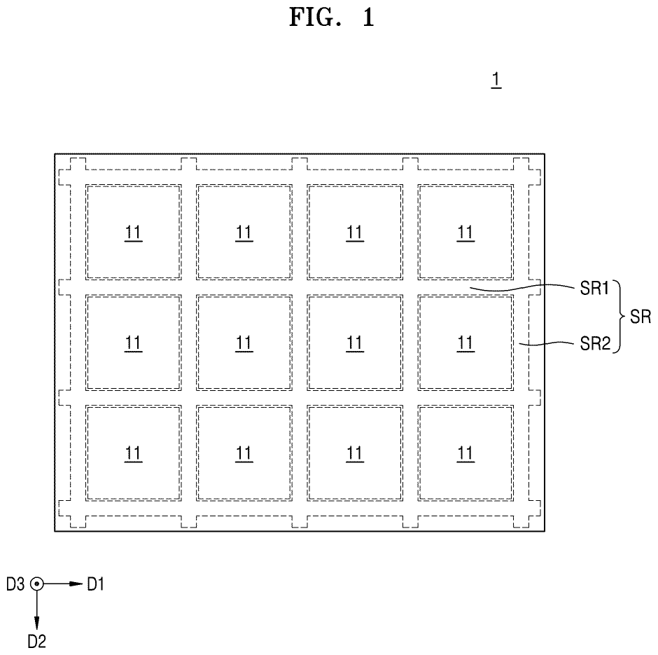

FIG. 1 is a plan view showing a circuit substrate 1 according to an embodiment.

Referring to FIG. 1, a substrate may be a circuit substrate 1. In an embodiment, the circuit substrate 1 may include a printed circuit board (PCB). The circuit substrate 1 may be a strip substrate or a panel substrate. In an embodiment, the circuit substrate 1 may have unit regions 11 and saw line regions SR in a plan view (e.g., in a plane defined in a first and second directions D1, D2). The unit regions 11 and the saw line regions SR may be virtual regions.

In an embodiment, each of the unit regions 11 may be a region used as a module substrate of a semiconductor module. In an embodiment, each of the unit regions 11 may be used as a package substrate of the semiconductor package. The unit regions 11 may be spaced apart from each other in the first direction D1 and/or the second direction D2. For example, in an embodiment the unit regions 11 may be arranged along rows extending in the first direction D1 and columns extending in the second direction D2. The second direction D2 may intersect with the first direction D1. A third direction D3 may intersect with the first direction D1 and the second direction D2. For example, in an embodiment the first to third directions D1 to D3 may be perpendicular to each other. However, embodiments of the present disclosure are not necessarily limited thereto and the first to third directions D1 to D3 may cross each other at various different angles.

For example, the saw line regions SR may respectively surround the unit regions 11 (e.g., in the first and second directions D1, D2). The saw line regions SR may be disposed between the unit regions 11. The saw line regions SR may include first saw line regions SR1 and second saw line regions SR2. The first saw line regions SR1 may extend in the first direction D1 and may be spaced apart from each other in the second direction D2. The second saw line regions SR2 may extend in a direction parallel to the second direction D2 and may be spaced apart from each other in the first direction D1. The second saw line regions SR2 may be connected to (e.g., directly connected thereto) the first saw line regions SR1.

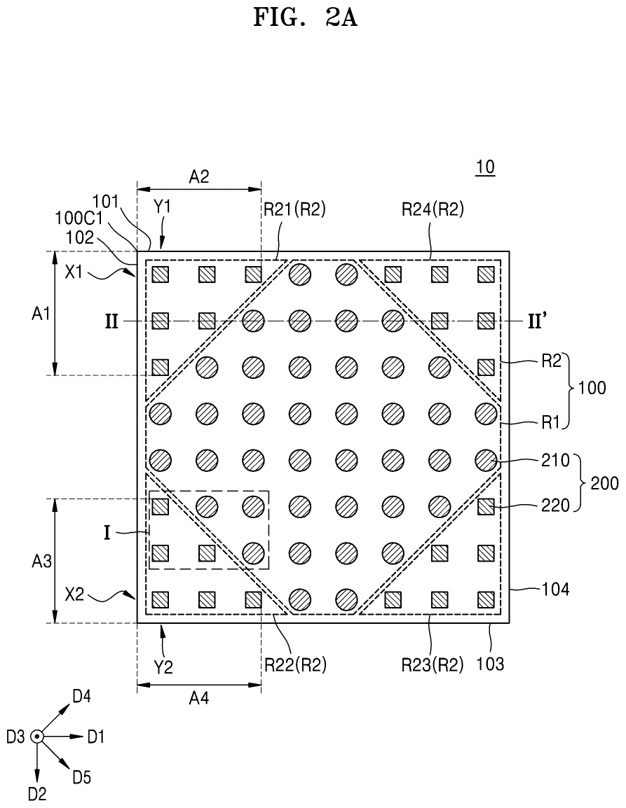

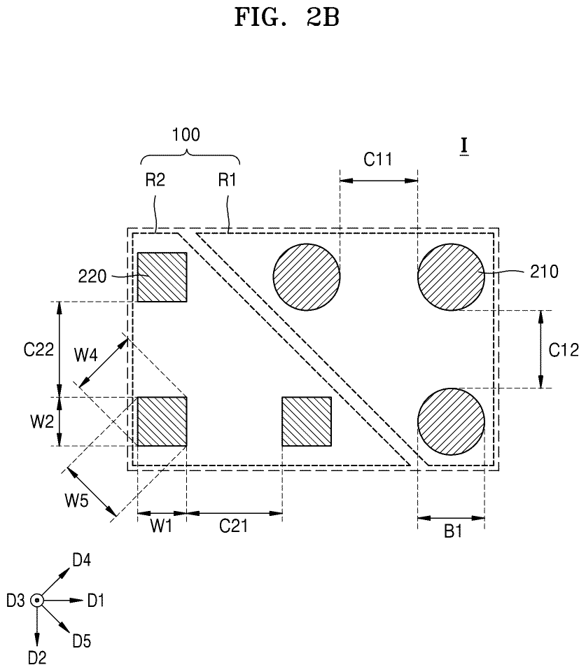

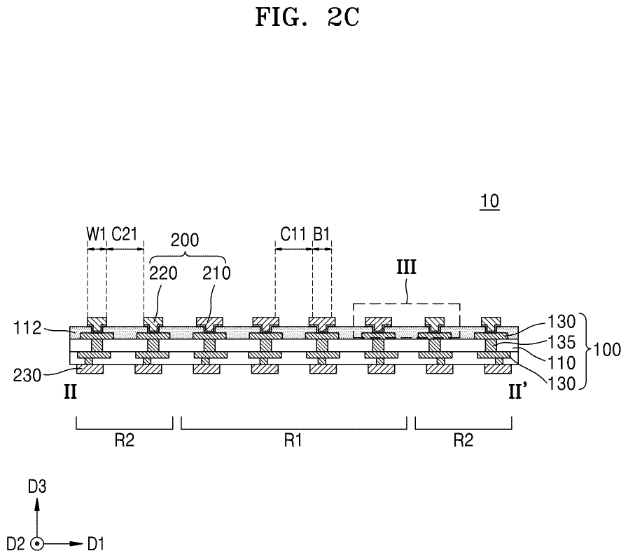

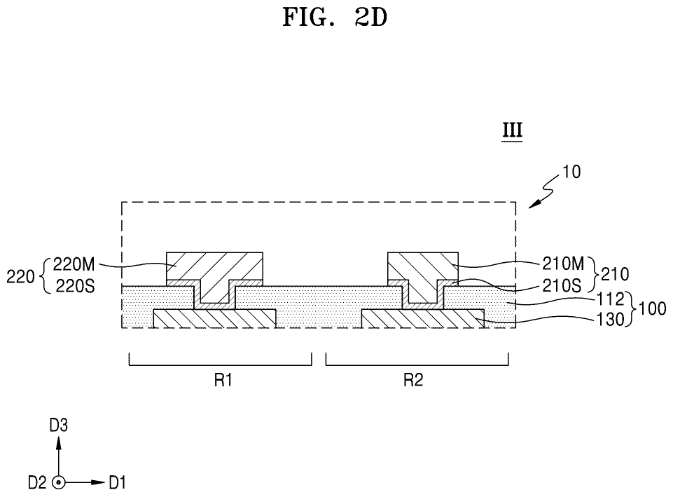

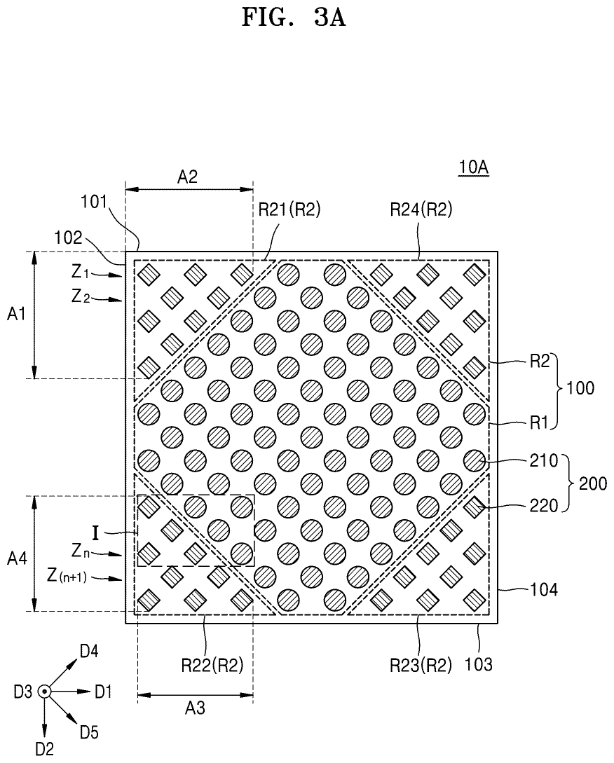

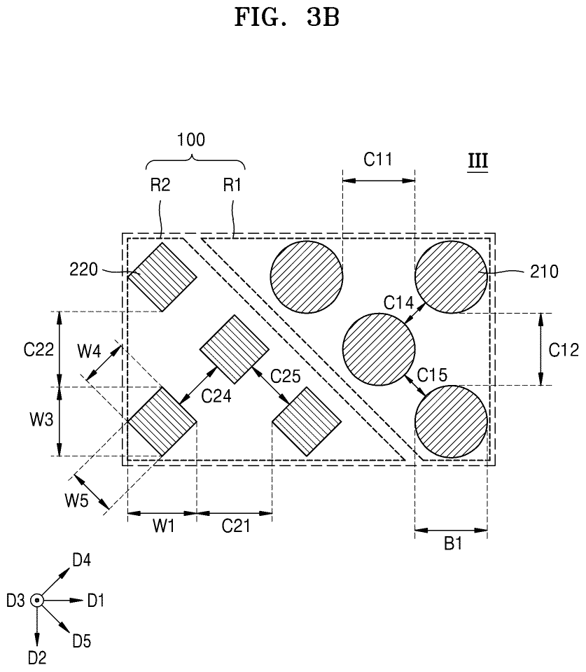

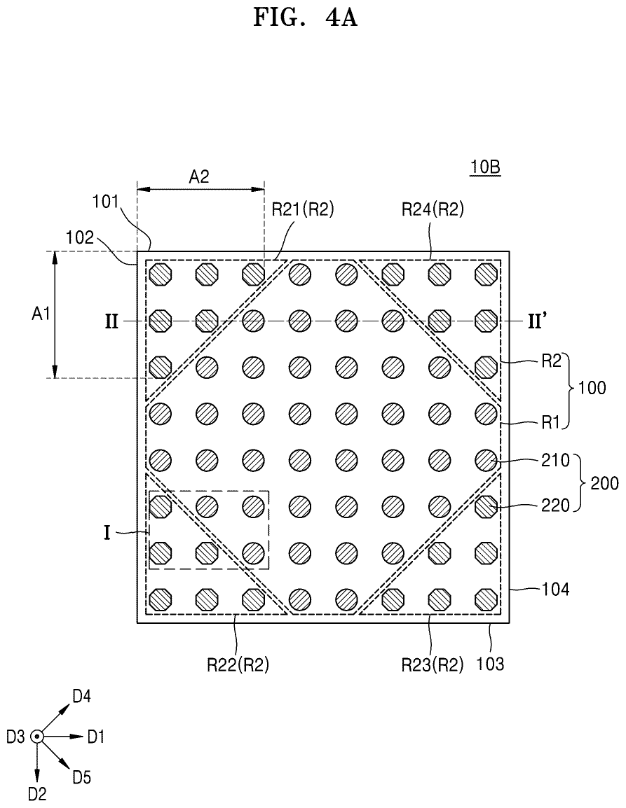

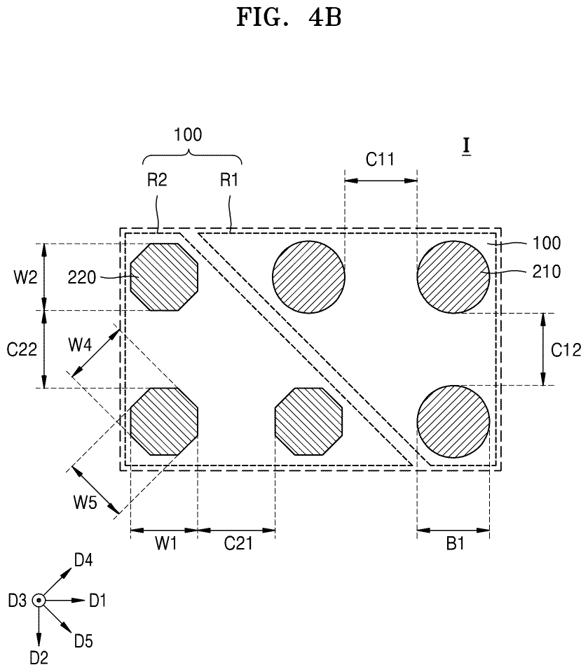

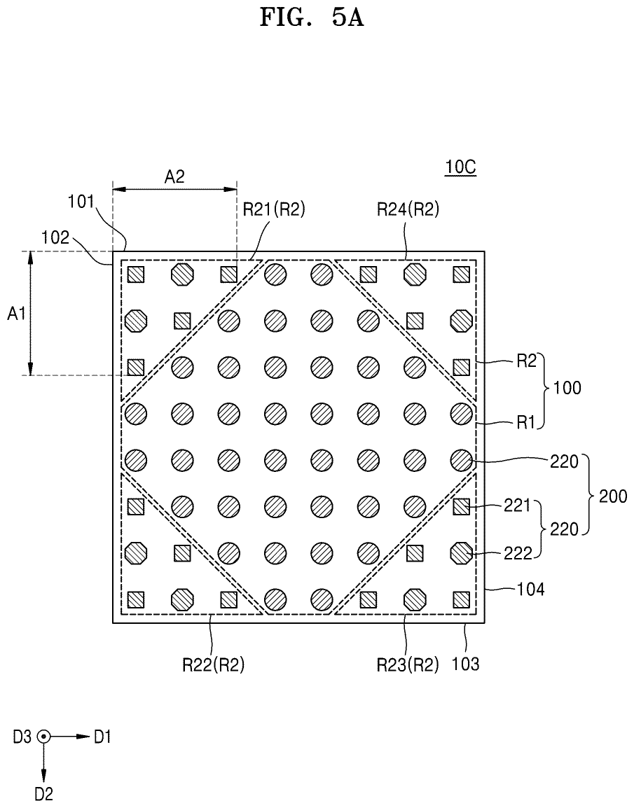

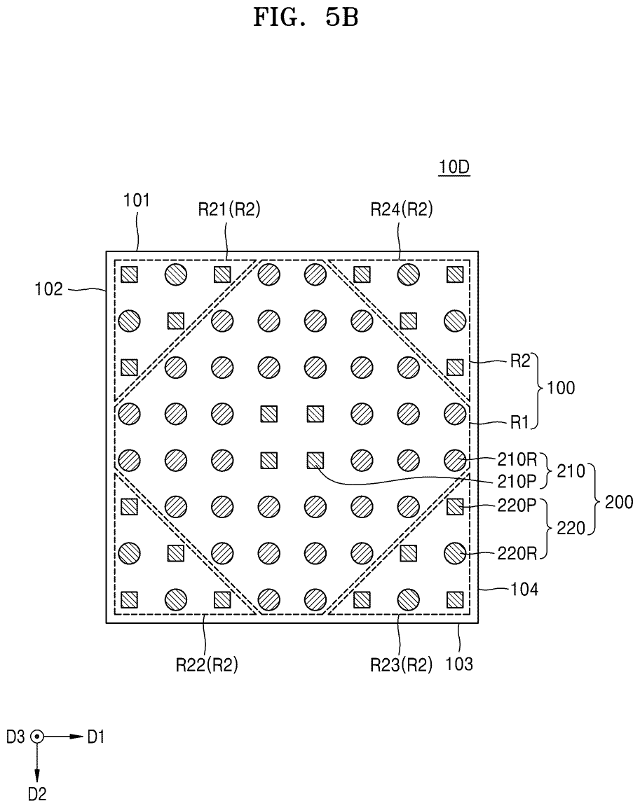

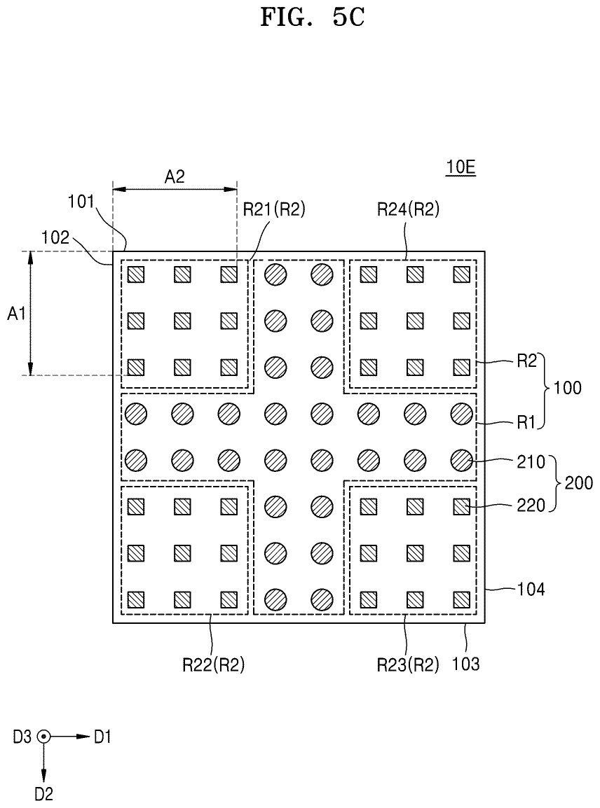

A sawing process of the circuit substrate 1 may be performed along the saw line regions SR. The saw line regions SR may be removed by the sawing process of the circuit substrate 1. Accordingly, the unit regions 11 of the circuit substrate 1 may be separated from each other such that a substrate 10 of FIGS. 2A to 2D, a substrate 10A of FIGS. 3A and 3B, a substrate 10B of FIGS. 4A and 4B, a substrate 10C of FIG. 5A, a substrate 10D of FIG. 5B, or a substrate 10E of FIG. 5C may be formed. Hereinafter, the substrates 10, 10A, 10B, 10C, 10D, and 10E according to some embodiments will be described. The descriptions of the substrates 10, 10A, 10B, 10C, 10D, and 10E may be equally applied to the unit regions 11 of the circuit substrate 1. However, side surfaces of the substrates 10, 10A, 10B, 10C, 10D, and 10E may respectively correspond to virtual side surfaces of the unit regions 11 of the circuit substrate 1 before the sawing process.

FIG. 2A is a plan view illustrating the substrate 10 according to an embodiment. FIG. 2B is an enlarged view of region I of FIG. 2A. FIG. 2C is a cross-section taken along line II-II′ of FIG. 2A. FIG. 2D is an enlarged view of region III of FIG. 2C.

Referring to FIGS. 2A to 2D, the substrate 10 may include a base substrate 100, conductive pads 200, and a protective layer 112. The substrate 10 may be a module substrate. As another example, the substrate 10 may be a package substrate.

In an embodiment, the base substrate 100 may include wiring patterns 130 and insulating layers 110, as shown in FIG. 2C. The insulating layers 110 may each include prepreg. In an embodiment, the insulating layers 110 may include an inorganic material such as glass fiber or an organic material such as epoxy resin. The first direction D1 and the second direction D2 may be parallel to an upper surface of the uppermost insulating layer 110. The third direction D3 may be substantially perpendicular to the upper surface of the uppermost insulating layer 110. The third direction D3 may be a vertical direction (e.g., a thickness direction of the base substrate 100).

The wiring patterns 130 may be disposed on one surface of a corresponding one of the insulating layers 110. The wiring patterns 130 may be disposed between the insulating layers 110. Some of the wiring patterns 130 may be spaced apart from each other. Certain components being spaced laterally may mean the components being spaced apart in a horizontal direction. “Horizontal” may mean parallel to an upper surface of the uppermost insulating layer 110. For example, “horizontal” may include parallel to the first direction D1 or the second direction D2. The other wiring patterns 130 may be vertically spaced apart from each other. In an embodiment, the wiring patterns 130 may include a metal material such as copper.

The base substrate 100 may further include conductive vias 135. The conductive vias 135 may be disposed within the insulating layers 110 and may penetrate the insulating layers 110. The conductive vias 135 may be provided between the wiring patterns 130 and may be electrically connected to the wiring patterns 130. In an embodiment, the conductive vias 135 may include a metal material such as copper.

Lower pads 230 may be disposed on a lower surface of the lowermost insulating layer 110. The lower pads 230 may be electrically connected to the wiring patterns 130. The lower pads 230 may be spaced apart laterally from each other (e.g., in a horizontal direction). In an embodiment, the lower pads 230 may each include a metal material such as copper, gold, nickel, and/or an alloy thereof.

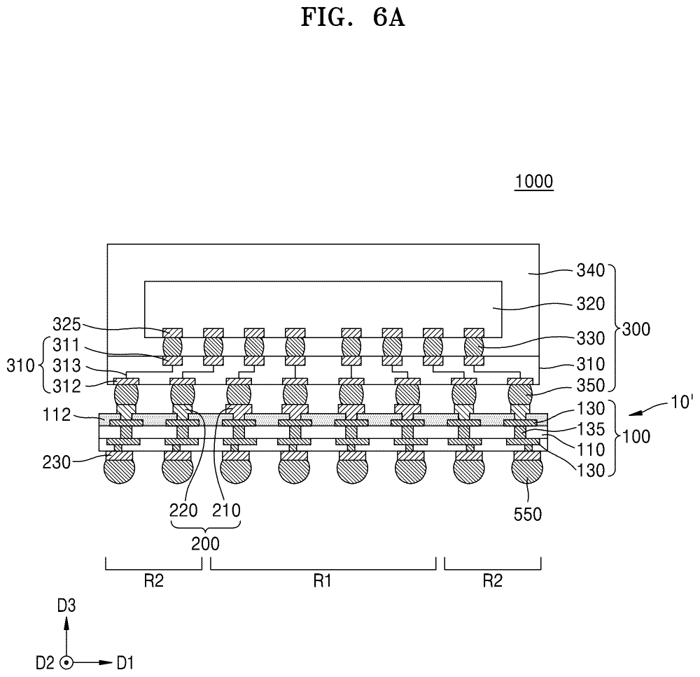

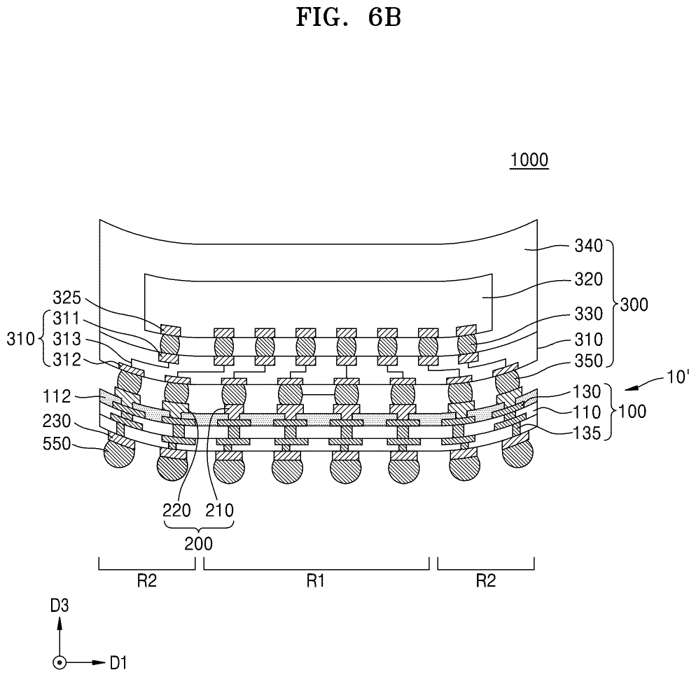

In an embodiment, the substrate 10 may further include solder ball terminals 550 as described below in FIG. 6A, and the solder ball terminals 550 may be disposed on (e.g., disposed directly thereon) lower surfaces of the lower pads 230.

The substrate 10 may further include the protective layer 112. The protective layer 112 may be disposed on an upper surface of the base substrate 100. The protective layer 112 may cover the upper surface of the uppermost insulating layer 110 and the corresponding wiring patterns 130. In an embodiment, the protective layer 112 may include a material different from the insulating layers 110. In an embodiment, the protective layer 112 may include, for example, an insulating polymer. The insulating polymer may include, for example, a solder resist material.

The base substrate 100 may include a center region R1 and a corner region R2 in a plan view, as shown in FIG. 2A. The base substrate 100 may include a plurality of corner regions R2. Each of the corner regions R2 of the base substrate 100 may be adjacent to a corner where two adjacent side surfaces of the base substrate 100 meet. In an embodiment, side surfaces of the base substrate 100 may have a first side surface 101, a second side surface 102, a third surface 103, and a fourth surface 104. The first side surface 101 and the second side surface 102 of the base substrate 100 may be adjacent to each other. The third surface 103 of the base substrate 100 may face the first side surface 101 (e.g., in the second direction D2) and may be adjacent to the second side surface 102. The fourth surface 104 of the base substrate 100 may face the second side surface 102 (e.g., in the first direction D1) and may be adjacent to the first side surface 101 and the third surface 103. The first side surface 101 and the third surface 103 of the base substrate 100 may extend in the first direction D1. The second side surface 102 and the fourth surface 104 of the base substrate 100 may extend in the second direction D2.

The conductive pads 200 may be disposed on the upper surface of the base substrate 100. For example, the conductive pads 200 may be disposed on the wiring patterns 130 and extend onto the upper surface of the protective layer 112. In an embodiment, the conductive pads 200 may include first conductive pads 210 and second conductive pads 220. The conductive pads 200 may be arranged along rows and columns in a plan view. The rows of the conductive pads 200 may extend in the first direction D1. The columns of the conductive pads 200 may extend in the second direction D2.

The first conductive pads 210 may be disposed on the upper surface of the center region R1 of the base substrate 100. The first conductive pads 210 may be arranged along rows and columns. In an embodiment, the first conductive pads 210 may each have a circular or oval planar shape (e.g., in a plane defined in the first and second directions D1, D2). The planar shape of each of the first conductive pads 210 may refer to the planar shape of the upper surface of each of the first conductive pads 210.

The second conductive pads 220 may be disposed on upper surfaces of the corner regions R2 of the base substrate 100. The second conductive pads 220 may be laterally spaced apart from the first conductive pads 210. In an embodiment, the second conductive pads 220 may have different planar shapes from those of the first conductive pads 210. For example, in an embodiment the second conductive pads 220 may each have a polygonal planar shape (e.g., in a plane defined in the first and second directions D1, D2). For example, in an embodiment each of the second conductive pads 220 may have a quadrangular planar shape. A quadrangle may include a rhombus, rectangle, or square. However, embodiments of the present disclosure are not necessarily limited thereto. For example, in an embodiment the planar shape of each of the first conductive pads 210 may be variously modified, such as a hexagon, an octagon, and/or a pentagon.

According to some embodiments, the second conductive pads 220 may be arranged in an array along rows and columns on each of the corner regions R2 of the base substrate 100. The numbers of the rows and columns of the first conductive pads 210 in the first center region R1 and the numbers of the rows and columns of the second conductive pads 220 in the corner regions R2 may vary. In each of the corner regions R2 of the base substrate 100, the second conductive pads 220 in one column may be aligned in the second direction D2. For example, the second conductive pads 220 in a first column may be aligned in the second direction D2. In an embodiment, each of the corner regions R2 of the base substrate 100 may have a triangular shape such as a right triangle in a plan view (e.g., in a plane defined in the first and second directions D1, D2). In each of the corner regions R2 of the base substrate 100, the array formed by the second conductive pads 220 may have a triangular shape.

According to an embodiment, the corner regions R2 of the base substrate 100 may include a first corner region R21, a second corner region R22, a third corner region R23, and a fourth corner region R24. The first corner region R21 of the base substrate 100 may be adjacent to a corner 100C1 where the first side surface 101 and the second side surface 102 of the base substrate 100 meet. In the first corner region R21 of the base substrate 100, the second conductive pads 220 in a first row X1 may be adjacent to the first side surface 101 of the base substrate 100 in a plan view (e.g., in a plane defined in the first and second directions D1, D2). For example, the second conductive pads 220 in the first row X1 may be disposed between the first side surface 101 of the base substrate 100 and the second conductive pads 220 in an (a+1) row (e.g., in the second direction D2). Here, a is a natural number of 1 or more. The second conductive pads 220 in an a row may be disposed between the first side surface 101 of the base substrate 100 and the second conductive pads 220 in the (a+1) row.

According to some embodiments, the number of second conductive pads 220 in the a row may be greater than the number of second conductive pads 220 in the (a+1) row. For example, the number of second conductive pads 220 in the first row X1 may be greater than the number of second conductive pads 220 in the (a+1) row.

In the first corner region R21 of the base substrate 100, the second conductive pads 220 in a first column Y1 may be adjacent to the second side surface 102 of the base substrate 100 in a plan view (e.g., in the first and second directions D1, D2). The second conductive pads 220 in the first column Y1 may be disposed between the second side surface 102 of the base substrate 100 and the second conductive pads 220 in a (b+1) column (e.g., in the first direction D1). Here, b is a natural number of 1 or more. The second conductive pads 220 in a b column may be disposed between the second side surface 102 of the base substrate 100 and the second conductive pads 220 in the (b+1) column. According to some embodiments, the number of second conductive pads 220 in the b column may be greater than the number of second conductive pads 220 in the (b+1) column. For example, the number of second conductive pads 220 in the first column Y1 may be greater than the number of second conductive pads 220 in the (b+1) column.

In the first corner region R21 of the base substrate 100, a maximum space A1 between the first side surface 101 of the base substrate 100 and the last row of the second conductive pads 220 may be in a range of about 15% to about 20% of a length of the second side surface 102 of the base substrate 100. The last row may include at least one second conductive pad 220. In the first corner region R21 of the base substrate 100, the maximum space A1 between the first side surface 101 of the base substrate 100 and the last row of the second conductive pads 220 may be the maximum space between the first side surface 101 of the base substrate 100 and an outer wall of at least one second conductive pad 220 in the last row. In the first corner region R21 of the base substrate 100, the outer wall of at least one second conductive pad 220 in the last row may face the first side surface 101 of the base substrate 100 (e.g., in the second direction D2).

In the first corner region R21 of the base substrate 100, the maximum space A2 between the second side surface 102 of the base substrate 100 and the last column of the second conductive pads 220 may be in a range of about 15% to about 20% of a length of the first side surface 101 of the base substrate 100. The last column may include at least one second conductive pad 220. For example, in the first corner region R21 of the base substrate 100, the maximum space A2 between the second side surface 102 of the base substrate 100 and the last column of the second conductive pads 220 may be the maximum space between the second side surface 102 of the base substrate 100 and an outer wall of at least one second conductive pad 220 in the last column. The outer wall of at least one second conductive pad 220 in the last column may face the second side surface 102 of the base substrate 100 (e.g., in the first direction D1).

The second corner region R22 of the base substrate 100 may be adjacent to a corner where the second side surface 102 and the third side surface 103 of the base substrate 100 meet. In the second corner region R22 of the base substrate 100, the second conductive pads 220 in a first row X2 may be adjacent to the third side surface 103 of the base substrate 100. For example, the second conductive pads 220 in the first row X2 may be disposed between the third side surface 103 of the base substrate 100 and the second conductive pads 220 in a (c+1) row (e.g., in the second direction D2). c is a natural number of 1 or more. The second conductive pads 220 in a c row may be disposed between the third side surface 103 of the base substrate 100 and the second conductive pads 220 in the (c+1) row. The number of second conductive pads 220 in the first row X2 may be greater than the number of second conductive pads 220 in the (c+1) row. In an embodiment, the number of second conductive pads 220 in the c row may be greater than the number of second conductive pads 220 in the (c+1) row. As an example, in an embodiment c may be the same as a. However, embodiments of the present disclosure are not necessarily limited thereto.

In an embodiment, in the second corner region R22 of the base substrate 100, the maximum space A3 between the third side surface 103 of the base substrate 100 and the last row of the second conductive pads 220 may be in a range of about 15% to about 20% of the length of the second side surface 102 of the base substrate 100. The last row may include at least one second conductive pad 220. In the second corner region R22 of the base substrate 100, the maximum space A3 between the third side surface 103 of the base substrate 100 and the last row of the second conductive pads 220 may be the maximum space between the third side surface 103 of 100 and the outer wall of at least one second conductive pad 220 in the last row. In the second corner region R22, the outer wall of at least one second conductive pad 220 in the last row may face the third side surface 103 of the base substrate 100 (e.g., in the second direction D2).

In the second corner region R22 of the base substrate 100, the second conductive pads 220 in a first column Y2 may be adjacent to the second side surface 102 of the substrate 10 (e.g., in the first direction D1). The second conductive pads 220 in the first column Y2 may be disposed between the second side surface 102 of the base substrate 100 and the second conductive pads 220 in a (d+1) column (e.g., in the first direction D1). d is a natural number of 1 or more. For example, the second conductive pads 220 in a d column may be disposed between the second side surface 102 of the base substrate 100 and the second conductive pads 220 in the (d+1) column (e.g., in the first direction D1). The number of second conductive pads 220 in the first column Y2 may be greater than the number of second conductive pads 220 in the (d+1) column. The number of second conductive pads 220 in the d column may be greater than the number of second conductive pads 220 in the (d+1) column. In an embodiment, d may be the same as b. However, embodiments of the present disclosure are not necessarily limited thereto.

In an embodiment, in the second corner region R22 of the base substrate 100, the maximum space A4 between the second side surface 102 of the base substrate 100 and the last column of the second conductive pads 220 may be in a range of about 15% to about 20% of a length of the third side surface 103 of the base substrate 100. The last column may include at least one second conductive pad 220. In the second corner region R22 of the base substrate 100, the maximum space A4 between the second side surface 102 of the base substrate 100 and the last column of the second conductive pads 220 may be the maximum space between the second side surface 102 of the base substrate 100 and the outer wall of at least one second conductive pad 220 in the last column. In the second corner region R22 of the base substrate 100, the outer wall of at least one second conductive pad 220 in the last column may face the second side surface 102 of the base substrate 100 (e.g., in the first direction D1).

The third corner region R23 of the base substrate 100 may be adjacent to a corner where the third side surface 103 and the fourth side surface 104 of the base substrate 100 meet. In the third corner region R23 of the base substrate 100, the second conductive pads 220 in a first row may be adjacent to the third side surface 103 of the base substrate 100 (e.g., in the second direction D2). The second conductive pads 220 in the first row may be disposed between the third side surface 103 of the base substrate 100 and the second conductive pads 220 in a (e+1) row (e.g., in the second direction D2). e is a natural number of 1 or more. For example, the second conductive pads 220 in an e row may be disposed between the third side surface 103 of the base substrate 100 and the second conductive pads 220 in the (e+1) row (e.g., in the second direction D2). The number of second conductive pads 220 in the first row may be greater than the number of second conductive pads 220 in the (e+1) row. The number of second conductive pads 220 in the e row may be greater than the number of second conductive pads 220 in the (e+1) row. As an example, in an embodiment e may be the same as at least one of c and a. However, embodiments of the present disclosure are not necessarily limited thereto.

In an embodiment, in the third corner region R23 of the base substrate 100, the maximum space between the third side surface 103 of the base substrate 100 and the last row of the second conductive pads 220 may be in a range of about 15% to about 20% of a length of the fourth side surface 104 of the base substrate 100.

In the third corner region R23 of the base substrate 100, the second conductive pads 220 in the first column may be adjacent to the fourth side surface 104 of the substrate 10 (e.g., in the first direction D1). The second conductive pads 220 in the first column may be disposed between the fourth side surface 104 of the base substrate 100 and the second conductive pads 220 in a (f+1) column (e.g., in the first direction D1). f is a natural number of 1 or more. For example, the second conductive pads 220 in an f column may be disposed between the fourth side surface 104 of the base substrate 100 and the second conductive pads 220 in the (f+1) column. The number of second conductive pads 220 in the first column may be greater than the number of second conductive pads 220 in the (f+1) column. The number of second conductive pads 220 in the f column may be greater than the number of second conductive pads 220 in the (f+1) column. In an embodiment, f may be the same as at least one of b and d. However, embodiments of the present disclosure are not necessarily limited thereto.

In an embodiment, in the third corner region R23 of the base substrate 100, the maximum space between the fourth side surface 104 of the base substrate 100 and the last column of the second conductive pads 220 may be in a range of about 15% to about 20% of the length of the third side surface 103 of the base substrate 100.

The fourth corner region R24 of the base substrate 100 may be adjacent to a corner where the first side surface 101 and the fourth side surface 104 of the base substrate 100 meet. In the fourth corner region R24 of the base substrate 100, the second conductive pads 220 in a first row may be adjacent to the first side surface 101 of the base substrate 100 (e.g., in the second direction D2). The second conductive pads 220 in the first row may be disposed between the first side surface 101 of the base substrate 100 and the second conductive pads 220 in a (g+1) row (e.g., in the second direction D2). g is a natural number of 1 or more. For example, the second conductive pads 220 in a g row may be disposed between the first side surface 101 of the base substrate 100 and the second conductive pads 220 in the (g+1) row. The number of second conductive pads 220 in the first row may be greater than the number of second conductive pads 220 in the (g+1) row. The number of second conductive pads 220 in the g row may be greater than the number of second conductive pads 220 in the (g+1) row. As an example, in an embodiment g may be the same as at least one of a, c, and e. However, embodiments of the present disclosure are not necessarily limited thereto.

In an embodiment, in the fourth corner region R24 of the base substrate 100, the maximum space between the first side surface 101 of the base substrate 100 and the last row of the second conductive pads 220 may be in a range of about 15% to about 20% of the length of the fourth side surface 104 of the base substrate 100.

In the fourth corner region R24 of the base substrate 100, the second conductive pads 220 in a first column may be adjacent to the fourth side surface 104 of the substrate 10 (e.g., in the first direction D1). The second conductive pads 220 in the first column may be disposed between the fourth side surface 104 of the base substrate 100 and the second conductive pads 220 in a (h+1) column (e.g., in the first direction D1). h is a natural number of 1 or more. For example, the second conductive pads 220 in an h column may be disposed between the fourth side surface 104 of the base substrate 100 and the second conductive pads 220 in the (h+1) column. The number of second conductive pads 220 in the first column may be greater than the number of second conductive pads 220 in the (h+1) column. The number of second conductive pads 220 in the h column may be greater than the number of second conductive pads 220 in the (h+1) column. In an embodiment, h may be the same as at least one of b, d, and f. However, embodiments of the present disclosure are not necessarily limited thereto.

In an embodiment, in the fourth corner region R24 of the base substrate 100, the maximum space between the fourth side surface 104 of the base substrate 100 and the last column of the second conductive pads 220 may be in a range of about 15% to about 20% of the length of the first side surface 101 of the base substrate 100.

In an embodiment in which the first conductive pads 210 each have a circular shape (e.g., in a plan view), diameters of the first conductive pads 210 in different directions may be substantially the same as each other. For example, as shown in FIG. 2B, a diameter B1 of each of the first conductive pads 210 in the first direction D1, the diameter of each of the first conductive pads 210 in the second direction D2, the diameter of each of the first conductive pads 210 in a first diagonal direction D4, and the diameter of each of the first conductive pads 210 in a second diagonal direction D5 may be substantially the same as each other. The maximum diameter of the first conductive pads 210 may correspond to the diameter B1 of each of the first conductive pads 210 in the first direction D1, the diameter of each of the first conductive pads 210 in the second direction D2, the diameter of each of the first conductive pads 210 in the first diagonal direction D4, and the diameter of each of the first conductive pads 210 in the second diagonal direction D5. The first diagonal direction D4 may be parallel to the upper surface of the uppermost insulating layer 110 and may intersect with the first direction D1 and the second direction D2. The second diagonal direction D5 may be parallel to the upper surface of the uppermost insulating layer 110 and may intersect with the first direction D1, the second direction D2, and the first diagonal direction D4. For example, in some embodiments, the first diagonal direction D4 and the second diagonal direction D5 may be perpendicular to each other and may intersect the first and second directions D1, D2 at an angle of 45°. However, embodiments of the present disclosure are not necessarily limited thereto.

The maximum width of the second conductive pads 220 may be a width in a direction different from the first direction D1 and the second direction D2. For example, the maximum width of the second conductive pads 220 may correspond to a space between two opposing vertices of the second conductive pads 220. Vertices of the second conductive pads 220 may face the first direction D1 and the second direction D2. The vertices of the second conductive pads 220 may extend in the first diagonal direction D4 or the second diagonal direction D5. However, embodiments of the present disclosure are not necessarily limited thereto. For example, the maximum width of the second conductive pads 220 may be a width W4 of each of the second conductive pads 220 in the first diagonal direction D4 or a width W5 of each of the second conductive pads 220 in the second diagonal direction D5.

The maximum width of the second conductive pads 220 may be the same as, or similar to, the maximum diameter of the first conductive pads 210. For example, in an embodiment the maximum width of the second conductive pads 220 may be in a range of about 95% to about 105% of the maximum diameter of the first conductive pads 210. Accordingly, a contact area between the second conductive pads 220 and solder balls 350 (FIGS. 6A and 6B) may be sufficiently secured.

The conductive pads 200 are arranged in rows extending in the first direction D1 and columns extending in the second direction D2, and thus, a space between the adjacent conductive pads 200 in the first direction D1 and a space between the adjacent conductive pads 200 in the second direction D2 may be relatively small. For example, any one of a space C11 between the adjacent first conductive pads 210 in the first direction D1 and a space C12 between the adjacent first conductive pads 210 in the second direction D2 may be the minimum space between the adjacent first conductive pads 210, and the other of these spaces may be a second relatively small space between the adjacent first conductive pads 210. Alternatively, each of a space C11 between the adjacent first conductive pads 210 in the first direction D1 and a space C12 between the adjacent first conductive pads 210 in the second direction D2 may be the minimum space between the adjacent first conductive pads 210.

In an embodiment, in a process of bonding the solder balls 350 of FIGS. 6A and 6B with the upper surfaces of the conductive pads 200, the corner regions R2 of the base substrate 100 may be bent in the third direction D3 or in a direction opposite to the third direction D3. In this embodiment, the space between the adjacent conductive pads 200 on the corner regions R2 of the base substrate 100 may be further reduced. However, when the minimum space between the adjacent conductive pads 200 on the corner regions R2 of the base substrate 100 is less than a certain amount, in the process of bonding the solder balls 350 of FIGS. 6A and 6B with the upper surfaces of the conductive pads 200, an electrical short may occur between the solder balls 350.

According to some embodiments of the present disclosure, the second conductive pads 220 each have a polygonal shape (e.g., in a plan view), and vertices of the polygon may face directions different from the first direction D1 and the second direction D2. In an embodiment, a width W1 of each of the second conductive pads 220 in the first direction D1 may be less than the diameter B1 of each of the first conductive pads 210 in the first direction D1. Accordingly, a space C21 between the adjacent second conductive pads 220 in the first direction D1 may be greater than the space C11 between the adjacent first conductive pads 210 in the first direction D1. Likewise, a width W2 of the second conductive pads 220 in the second direction D2 may be less than the diameter of each of the first conductive pads 210 in the second direction D2. Accordingly, a space C22 between the adjacent second conductive pads 220 in the second direction D2 may be greater than the space C12 between the adjacent first conductive pads 210 in the second direction D2. According to some embodiments, the minimum space between the adjacent second conductive pads 220 may be sufficiently secured. Accordingly, in the process of bonding the solder balls 350 to the upper surfaces of the second conductive pads 220, an occurrence of the electrical short between the solder balls 350 may be prevented.

As shown in FIGS. 2C and 2D, the first conductive pads 210 and the second conductive pads 220 may extend further into the protective layer 112. The first conductive pads 210 and the second conductive pads 220 may be connected to (e.g., directly connected thereto) the wiring patterns 130. Accordingly, the first conductive pads 210 and the second conductive pads 220 may be electrically connected to the lower pads 230 through the wiring patterns 130. In an embodiment, at least one of the first conductive pads 210 and the second conductive pads 220 may not be vertically aligned with the lower pads 230 electrically connected thereto. Accordingly, a degree of freedom of arrangement of the conductive pads 200 may be increased. The respective lower portions of the first conductive pads 210 and the second conductive pads 220 may be disposed within the protective layer 112. In an embodiment, the respective lower portions of the first conductive pads 210 and the second conductive pads 220 may each have a circular or oval shape in a plan view (e.g., in a plane defined in the first and second directions D1, D2). However, embodiments of the present disclosure are not necessarily limited thereto.

In an embodiment, the first conductive pads 210 may each include a first seed pattern 210S and a first metal pad 210M, as shown in FIG. 2D. The first seed pattern 210S may be disposed between the first metal pad 210M and the corresponding wiring pattern 130 (e.g., in the third direction D3) and may extend between the first metal pad 210M and the protective layer 112. In an embodiment, a thickness (e.g., length in the third direction D3) of the first seed pattern 210S may be less than a thickness (e.g., length in the third direction D3) of the first metal pad 210M. The first seed pattern 210S may include a material different from that of the first metal pad 210M. The first seed pattern 210S may include a conductive seed material. For example, in an embodiment, the conductive seed material may include titanium and/or titanium-copper alloy. The first metal pad 210M may include copper or a copper alloy. However, embodiments of the present disclosure are not necessarily limited thereto.

In an embodiment, the second conductive pads 220 may each include a second seed pattern 220S and a second metal pad 220M. The second seed pattern 220S may be disposed between the second metal pad 220M and the corresponding wiring pattern 130 (e.g., in the third direction D3) and may extend between the second metal pad 220M and the protective layer 112. A thickness (e.g., length in the third direction D3) of the second seed pattern 220S may be less than a thickness (e.g., length in the third direction D3) of the second metal pad 220M. The second seed pattern 220S may include a material different from that of the second metal pad 220M. The second seed pattern 220S may include a conductive seed material. In an embodiment, the second metal pad 220M may include copper or a copper alloy. However, embodiments of the present disclosure are not necessarily limited thereto.

FIG. 3A is a plan view illustrating the substrate 10A according to some embodiments. FIG. 3B is an enlarged view of region I of FIG. 3A. Hereinafter, descriptions redundant with those given above are omitted.

Referring to FIGS. 3A and 3B, the substrate 10A may include the base substrate 100 and the conductive pads 200. The substrate 10A may further include at least one of the protective layer 112 and the lower pads 230 described in FIG. 2C. The base substrate 100, the conductive pads 200, the protective layer 112, and the lower pads 230 may be similar to those described in the examples of FIGS. 2A to 2D.

The conductive pads 200 may include the first conductive pads 210 and the second conductive pads 220. The conductive pads 200 may be arranged along rows and columns in a plan view. The conductive pads 200 in a first row may be adjacent to the first side surface 101 of the base substrate 100. However, in an embodiment the conductive pads 200 may be arranged in a zigzag pattern in a plan view (e.g., in a plane defined in the first and second directions D1, D2). For example, the conductive pads 200 in an (n+1) row Z₍ₙ₊₁₎ may be arranged shifted (e.g., offset) in the first direction D1 from the conductive pads 200 in an n row Zₙ. n is a natural number of 1 or more. For example, the conductive pads 200 in a second row Z₂ may be arranged shifted (e.g., offset) in the first direction D1 from the conductive pads 200 in a first row Z₁. Accordingly, the second conductive pads 220 in one row may not be aligned with each other in the second direction D2. For example, along a column, the second conductive pad 220 corresponding to the (n+1) row Z₍ₙ₊₁₎ may not be aligned in the second direction D2 with the second conductive pad 220 corresponding to the n row Zₙ.

In an embodiment, a space between the adjacent conductive pads 200 in the first diagonal direction D4 and a space between the adjacent conductive pads 200 in the second diagonal direction D5 may each be less than spaces between the adjacent conductive pads 200 in the first direction D1. In an embodiment, the space between the conductive pads 200 in the first diagonal direction D4 and the space between the conductive pads 200 in the second diagonal direction D5 may each be less than spaces between the conductive pads 200 in the second direction D2.

In an embodiment, the first conductive pads 210 may each have a circular or oval planar shape (e.g., in a plane defined in the first and second directions D1, D2). As shown in FIG. 3B, a space C14 between the adjacent first conductive pads 210 in the first diagonal direction D4 and a space C15 between the adjacent first conductive pads 210 in the second diagonal direction D5 may each be less than the space C11 between the adjacent first conductive pads 210 in the first direction D1. Alternatively, the space C14 between the adjacent first conductive pads 210 in the first diagonal direction D4 and the space C15 between the adjacent first conductive pads 210 in the second diagonal direction D5 may each be less than the space C12 between the adjacent first conductive pads 210 in the second direction D2.

In an embodiment, one of the space C14 between the adjacent first conductive pads 210 in the first diagonal direction D4 and the space C15 between the adjacent first conductive pads 210 in the second diagonal direction D5 may be the minimum space between the adjacent first conductive pads 210, and the other space may be the second smallest space between the adjacent first conductive pads 210. Alternatively, the space C14 between the adjacent first conductive pads 210 in the first diagonal direction D4 and the space C15 between the adjacent first conductive pads 210 in the second diagonal direction D5 may each be the minimum space between the conductive pads 210.

In an embodiment, a space C24 between the adjacent second conductive pads 220 in the first diagonal direction D4 and a space C25 between the adjacent second conductive pads 220 in the second diagonal direction D5 may each be less than the space C21 between the adjacent second conductive pads 220 in the first direction D1. The space C24 between the adjacent second conductive pads 220 in the first diagonal direction D4 and the space C25 between the adjacent second conductive pads 220 in the second diagonal direction D5 may each be less than the space C22 between the adjacent second conductive pads 220 in the second direction D2.

In an embodiment, any one of the space C24 between the second conductive pads 220 in the first diagonal direction D4 and the space C25 between the second conductive pads 220 in the second diagonal direction D5 may be the minimum space between the adjacent second conductive pads 220, and the other space may be the second smallest space between the adjacent second conductive pads 220. Alternatively, the space C24 between the adjacent second conductive pads 220 in the first diagonal direction D4 and the space C25 between the adjacent second conductive pads 220 in the second diagonal direction D5 may each be the minimum space between the second conductive pads 220.

According to some embodiments, the second conductive pads 220 may have a rectangular shape in a plan view (e.g., in a plane defined in the first and second directions D1, D2). However, unlike previously described embodiments, vertices of the second conductive pads 220 may face directions different from the first diagonal direction D4 and the second diagonal direction D5. For example, the maximum width of the second conductive pads 220 may be measured in a direction different from the first diagonal direction D4 and the second diagonal direction D5. For example, in an embodiment the vertices of the second conductive pads 220 may face the first direction D1 and the second direction D2. However, embodiments of the present disclosure are not necessarily limited thereto.

The maximum width of the second conductive pads 220 may correspond to the width W1 of the second conductive pads 220 in the first direction D1 and/or the width W2 of the second conductive pads 220 in the second direction D2. The width W4 of the second conductive pads 220 in the first diagonal direction D4 and the width W5 of the second conductive pads 220 in the second diagonal direction D5 may each be less than the width W1 of the second conductive pads 220 in the first direction D1. The width W4 of the second conductive pads 220 in the first diagonal direction D4 and the width W5 of the second conductive pads 220 in the second diagonal direction D5 may each be less than the width W2 of the second conductive pads 220 in the second direction D2. For example, the width W4 of the second conductive pads 220 in the first diagonal direction D4 and the width W5 of the second conductive pads 220 in the second diagonal direction D5 may each be less than the maximum width of the second conductive pads 220. In an embodiment, the maximum width of the second conductive pads 220 may be in a range of about 95% to about 105% of the maximum diameter of the first conductive pads 210. The width W4 of the second conductive pads 220 in the first diagonal direction D4 may be less than the diameter of the first conductive pads 210 in the first diagonal direction D4. Accordingly, the space C24 between the adjacent second conductive pads 220 in the first diagonal direction D4 may be greater than the space C14 between the adjacent first conductive pads 210 in the first diagonal direction D4. The width W5 of the second conductive pads 220 in the second diagonal direction D5 may be less than the diameter of the first conductive pads 210 in the second diagonal direction D5. Accordingly, the space C25 between the adjacent second conductive pads 220 in the second diagonal direction D5 may be greater than the space C15 between the adjacent first conductive pads 210 in the second diagonal direction D5. Accordingly, the minimum space between the adjacent second conductive pads 220 may be sufficiently secured.

FIG. 4A is a plan view illustrating the substrate 10B according to some embodiments. FIG. 4B is an enlarged view of region I of the substrate 10B of FIG. 4A. Hereinafter, in the descriptions of FIGS. 4A and 4B, FIGS. 2C and 2D are referred to together, and descriptions redundant with those given above are omitted for economy of description. A cross-section of FIG. 4A taken along line II-II′ may be similar to FIG. 2C.

Referring to FIGS. 4A and 4B, the substrate 10B may include the base substrate 100 and the conductive pads 200. The substrate 10B may further include at least one of the protective layer 112 and the lower pads 230 described with reference to FIG. 2C. The first conductive pads 210 may be disposed on an upper surface of the center region R1 of the base substrate 100. In an embodiment, the first conductive pads 210 may have a circular or oval planar shape (e.g., in a plane defined in the first and second directions D1, D2).

The second conductive pads 220 may be disposed on the upper surface of the corner regions R2 of the base substrate 100. In an embodiment, the second conductive pads 220 may have an octagonal shape in a plan view (e.g., in a plane defined in the first and second directions D1, D2). Columns of the conductive pads 200 may extend in the second direction D2. In this embodiment, vertices of the second conductive pads 220 may face directions different from the second direction D2, as shown in FIG. 4B. The vertices of the second conductive pads 220 may face directions different from the first direction D1. In an embodiment, at least one of the vertices of the second conductive pads 220 may face the first diagonal direction D4 or the second diagonal direction D5. The maximum width of the second conductive pads 220 may be the width W4 of the second conductive pads 220 in the first diagonal direction D4 or the width W5 of the second conductive pads 220 in the second diagonal direction D5.

The width W1 of the second conductive pads 220 in the first direction D1 and the width W2 of the second conductive pads 220 in the second direction D2 may each be less than the maximum width of the second conductive pads 220. In an embodiment, the maximum width of the second conductive pads 220 may be in a range of about 95% to about 105% of the diameter (e.g., the maximum diameter) of the first conductive pads 210. The width W1 of the second conductive pads 220 in the first direction D1 may be less than the diameter B1 of the first conductive pads 210 in the first direction D1. Accordingly, the space C21 between the adjacent second conductive pads 220 in the first direction D1 may be greater than the space C11 between the adjacent first conductive pads 210 in the first direction D1.

The width W2 of the second conductive pads 220 in the second direction D2 may be less than the diameter of the first conductive pads 210 in the second direction D2. Accordingly, the space C22 between the adjacent second conductive pads 220 in the second direction D2 may be greater than the space C12 between the adjacent first conductive pads 210 in the second direction D2.

In an embodiment, the conductive pads 200 may be arranged in a zigzag manner as described in the example of FIG. 3A. In this embodiment, the space between the conductive pads 200 in the first diagonal direction D4 and the space between the conductive pads 200 in the second diagonal direction D5 may be less than the space between the conductive pads 200 in the first direction D1 and the space between the conductive pads 200 in the second direction D2. Accordingly, vertices of the second conductive pads 220 may face directions different from the first diagonal direction D4 and the second diagonal direction D5. For example, at least some of the vertices of the second conductive pads 220 may face the first direction D1 and the second direction D2. Accordingly, as described in the examples of FIGS. 3A and 3B, the space between the second conductive pads 220 in the first diagonal direction D4 may be greater than the space between the first conductive pads 210 in the first diagonal direction D4. The space between the second conductive pads 220 in the second diagonal direction D5 may be greater than the space between the first conductive pads 210 in the second diagonal direction D5.

FIG. 5A is a plan view illustrating the substrate 10C according to some embodiments. Hereinafter, descriptions redundant with those given above are omitted for economy of description.

Referring to FIG. 5A, the substrate 10C may include the base substrate 100 and the conductive pads 200. The substrate 10C may further include at least one of the protective layer 112 and the lower pads 230 described with reference to FIG. 2C.

In an embodiment, the second conductive pads 220 may include a first sub-conductive pad 221 and a second sub-conductive pad 222. The first sub-conductive pad 221 may have a polygonal planar shape (e.g., in a plane defined in the first and second directions D1, D2). The second sub-conductive pad 222 may have a polygonal planar shape (e.g., in a plane defined in the first and second directions D1, D2) that is different from that of the first sub-conductive pad 221. For example, in an embodiment the first sub-conductive pad 221 may have a quadrangular planar shape, and the second sub-conductive pad 222 may have an octagonal planar shape. However, embodiments of the present disclosure are not necessarily limited thereto. In an embodiment, the second conductive pads 220 may further include a third sub-conductive pad. In this embodiment, the third sub-conductive pad may have a polygonal planar shape different from those of the first sub-conductive pad 221 and the second sub-conductive pad 222. In some embodiments, the second conductive pads 220 may further include fourth sub-conductive pads or greater, each having different polygonal planar shapes from the first to third sub-conductive pads.

FIG. 5B is a plan view illustrating the substrate 10D according to some embodiments. Hereinafter, descriptions redundant with those given above are omitted for economy of description.

Referring to FIG. 5B, the substrate 10D may include the base substrate 100 and the conductive pads 200. The substrate 10D may further include at least one of the protective layer 112 and the lower pads 230 described with reference to FIG. 2C.

The first conductive pads 210 may be disposed on the center region R1 of the base substrate 100. In an embodiment, the first conductive pads 210 may include first round conductive pads 210R and first polygonal conductive pads 210P. The first round conductive pads 210R may each have a circular or oval planar shape (e.g., in a plane defined in the first and second directions DR1, DR2). The first polygonal conductive pad 210P may have, for example, a quadrangular, hexagonal, or octagonal planar shape. The number of first round conductive pads 210R may be greater than the number of first polygonal conductive pads 210P.

The second conductive pads 220 may be disposed on the corner regions R2 of the base substrate 100. In an embodiment, the second conductive pads 220 may include second polygonal conductive pads 220P and second round conductive pads 220R. In an embodiment, the second polygonal conductive pads 220P may each have, for example, a quadrangular, hexagonal, or octagonal planar shape (e.g., in a plane defined in the first and second directions DR1, DR2). The second round conductive pad 220R may have a circular or oval planar shape (e.g., in a plane defined in the first and second directions DR1, DR2). In an embodiment, the number of second polygonal conductive pads 220P may be greater than the number of second round conductive pads 220R.

FIG. 5C is a plan view illustrating the substrate 10E according to some embodiments. Hereinafter, descriptions redundant with those given above are omitted for economy of description.

Referring to FIG. 5C, the substrate 10E may include the base substrate 100 and the conductive pads 200. The substrate 10E may further include at least one of the protective layer 112 and the lower pads 230 described with reference to FIG. 2C.

Each of the corner regions R2 of the base substrate 100 may have a quadrangular planar shape. In each of the corner regions R2 of the base substrate 100, the second conductive pads 220 may be arranged along rows and columns. An array formed by the second conductive pads 220 in at least one of the corner regions R2 of the base substrate 100 may have a quadrangular shape. For example, in at least one of the corner regions R2 of the base substrate 100, the number of second conductive pads 220 in one row may be the same as the number of second conductive pads 220 in another row. In the at least one corner region R2, the number of second conductive pads 220 in one column may be the same as the number of second conductive pads 220 in another column. For example, as shown in FIG. 5C, each of the corner regions R2 may have a same number of second conductive pads 220 in both the rows and the columns, respectively.

Embodiments of the present inventive concept may be combined with each other. At least two of embodiments of FIGS. 2A to 2D, embodiments of FIGS. 3A and 3B, embodiments of FIGS. 4A and 4B, an embodiment of FIG. 5A, an embodiment of FIG. 5B, and an embodiment of FIG. 5C may be combined with each other. For example, in the substrate 10C of FIG. 5A, the substrate 10D of FIG. 5B, or the substrate 10E of FIG. 5C, the conductive pads 200 may be arranged in a zigzag manner as described in embodiments of FIGS. 3A and 3B. In this embodiment, the arrangement of the second conductive pads 220 may be modified as shown in embodiments of FIGS. 3A and 3B.

FIG. 6A is a cross-sectional view showing a semiconductor module 1000 according to an embodiment. FIG. 6B is a cross-sectional view showing the semiconductor module 1000 during a reflow process according to an embodiment.

Referring to FIGS. 6A and 6B, the semiconductor module 1000 may include a module substrate 10′, the solder ball terminals 550, and a semiconductor package 300. For example, the substrate 10 described in embodiments of FIGS. 2A to 2D may be used as the module substrate 10′. As another example, the substrate 10A of embodiments of FIGS. 3A and 3B, the substrate 10B of embodiments of FIGS. 4A and 4B, the substrate 10C of an embodiment of FIG. 5A, the substrate 10D of an embodiment of FIG. 5B, or the substrate 10E of an embodiment of FIG. 5C may be used as the module substrate 10′. Hereinafter, for convenience, it is mainly described that the substrate 10 described in embodiments of FIGS. 2A to 2D is used as the module substrate 10′. However, embodiments of the present disclosure are not necessarily limited thereto. The module substrate 10′ may include the base substrate 100, the conductive pads 200, the protective layer 112, and the lower pads 230. The base substrate 100 may have the center region R1 and the corner regions R2.

The solder ball terminals 550 may be disposed on a lower surface of the substrate 10′ and may be electrically connected to the lower pads 230. The solder ball terminals 550 may each include a solder material. In an embodiment, the solder material may include tin (Sn), silver (Ag), zinc (Zn), and/or an alloy thereof.

The semiconductor package 300 may be disposed on an upper surface of the module substrate 10′. In an embodiment, the semiconductor package 300 may include a package substrate 310, a semiconductor chip 320, the solder balls 350, bumps 330, and a molding layer 340. A PCB or a redistribution layer may be used as the package substrate 310. The package substrate 310 may include lower metal pads 312, metal wirings 313, and upper metal pads 311. The lower metal pads 312 and the upper metal pads 311 may be disposed on lower and upper surfaces of the package substrate 310, respectively. The lower metal pads 312 may be electrically connected to the upper metal pads 311 respectively through the metal wirings 313.

The semiconductor chip 320 may be disposed on the upper surface of the package substrate 310. In an embodiment, the semiconductor chip 320 may include a memory circuit, a logic circuit, and a combination thereof. For example, in an embodiment chip pads 325 of the semiconductor chip 320 may be disposed on a lower surface of the semiconductor chip 320. The bumps 330 may be disposed between the package substrate 310 and the semiconductor chip 320 and connected to the upper metal pads 311 and the chip pads 325. Accordingly, the semiconductor chip 320 may be electrically connected to the package substrate 310. In an embodiment, the bumps 330 may each include metal, such as a solder material. As another example, the chip pads 325 may be disposed on an upper surface of the semiconductor chip 320, and the semiconductor chip 320 may be electrically connected to the package substrate 310 through bonding wirings. As another example, the semiconductor package 300 may include a plurality of semiconductor chips 320.

The solder balls 350 may be disposed on the lower surface of the package substrate 310 and connected to the lower metal pads 312. In an embodiment, the solder balls 350 may each include a solder material.

In an embodiment, mounting the semiconductor package 300 on the module substrate 10′ may include bonding the solder balls 350 to the conductive pads 200 through the reflow process. In an embodiment, the reflow process may be performed at a temperature higher than room temperature (e.g., 26° C.). In the reflow process, warpage of the semiconductor module 1000 may occur due to the difference in the thermal expansion coefficient between components of the semiconductor module 1000. For example, warpage may occur in the corner regions R2 of the base substrate 100 and corner regions of the semiconductor package 300. For example, in some instances the module substrate 10′ may be warped in a smile shape. Upper surfaces of the corner regions R2 of the base substrate 100 may be provided at a higher level than an upper surface of the center region R1 of the base substrate 100. In this case, in the reflow process, spaces between the upper surfaces of the corner regions R2 of the base substrate 100 and the package substrate 310 may be less than a space between the upper surface of the center region R1 of the base substrate 100 and the package substrate 310. When the second conductive pads 220 have the same planar shapes as the first conductive pads 210, an electrical short may occur between the solder balls 350 on the corner regions R2 of the base substrate 100 during the reflow process.

According to some embodiments, the second conductive pads 220 may have different planar shapes from those of the first conductive pads 210. The shapes and arrangement of the second conductive pads 220 may be arranged to increase the minimum space between adjacent second conductive pads 220. For example, the minimum space between the adjacent second conductive pads 220 may be greater than the minimum space between the adjacent first conductive pads 210. The second smallest space between the adjacent second conductive pads 220 may be greater than the second smallest space between the adjacent first conductive pads 210. Accordingly, even though warpage of the module substrate 10′ occurs during the reflow process, an occurrence of the electrical short between the solder balls 350 connected to the solder balls 350 may be prevented. According to some embodiments, the manufacturing yield of the semiconductor module 1000 may be increased, and the semiconductor module 1000 may exhibit increased reliability.

According to some embodiments, as described in the example of FIG. 2A, an array formed by the second conductive pads 220 in each of the corner regions R2 of the base substrate 100 may have a triangular shape. For example, as the rows or columns formed by the second conductive pads 220 are adjacent to the first to fourth side surfaces 101, 102, 103, and 104 of the base substrate 100, the number of second conductive pads 220 included in the columns or rows may be increased. Accordingly, even though warpage intensively occurs in the corner regions R2 of the base substrate 100, the occurrence of the electrical short between the solder balls 350 on the corner regions R2 of the base substrate 100 may be more effectively prevented by the second conductive pads 220.

In an embodiment, the first conductive pads 210 each have a circular or oval shape in a plan view, and thus, the area of the upper surface of each of the first conductive pads 210 may be relatively large. Accordingly, a contact area between the first conductive pads 210 and the solder balls 350 is increased, and thus, the solder balls 350 may be stably bonded to the first conductive pads 210.

In an embodiment, the maximum width of the second conductive pads 220 may be in a range of about 96% to about 106% of the maximum diameter of the first conductive pads 210. Accordingly, the contact area between the second conductive pads 220 and the solder balls 350 may be sufficiently secured.

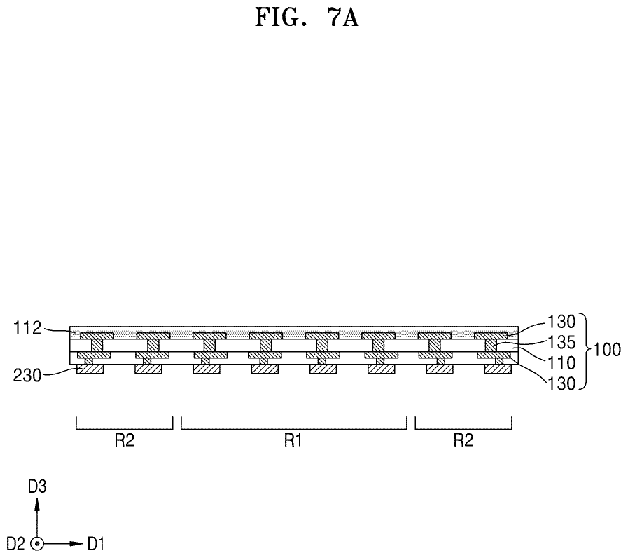

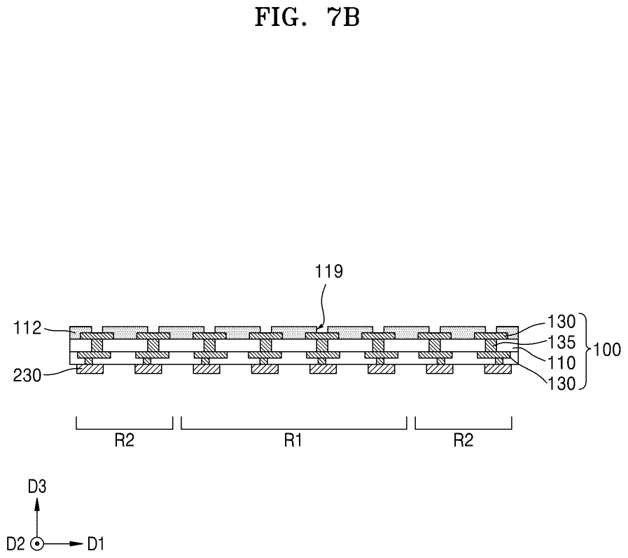

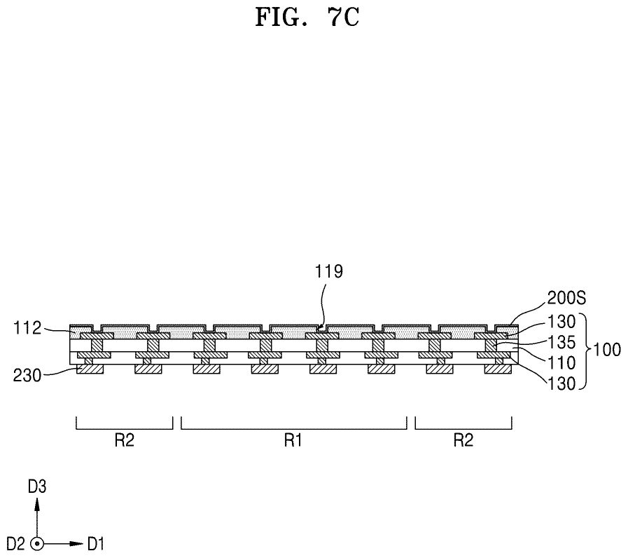

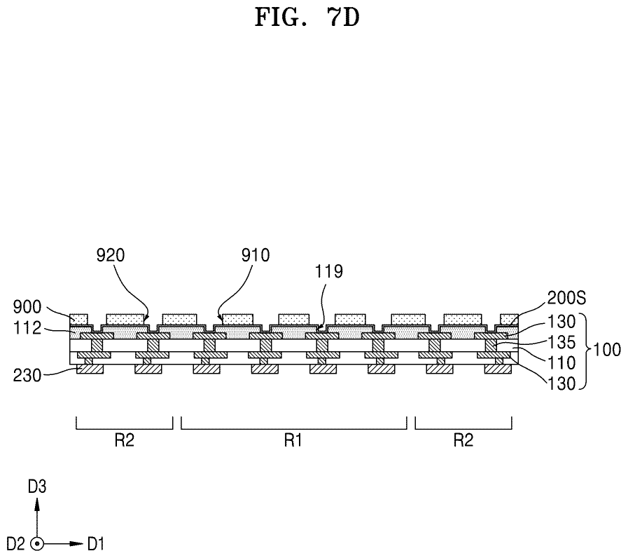

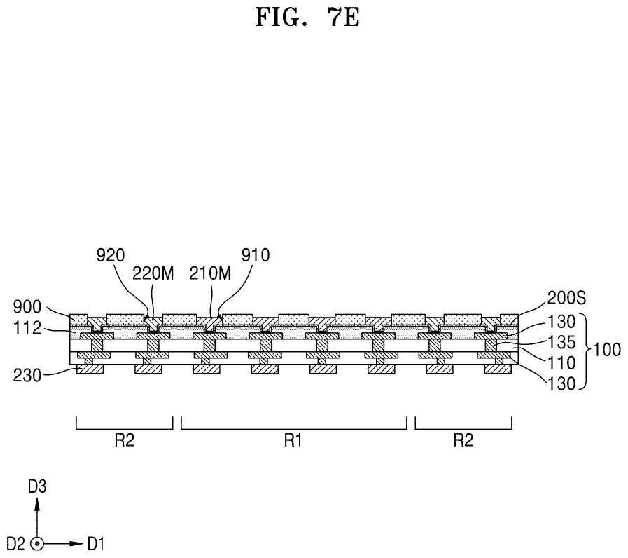

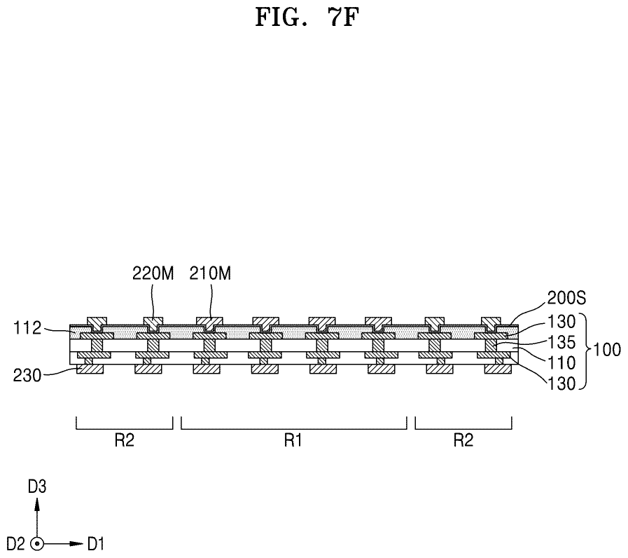

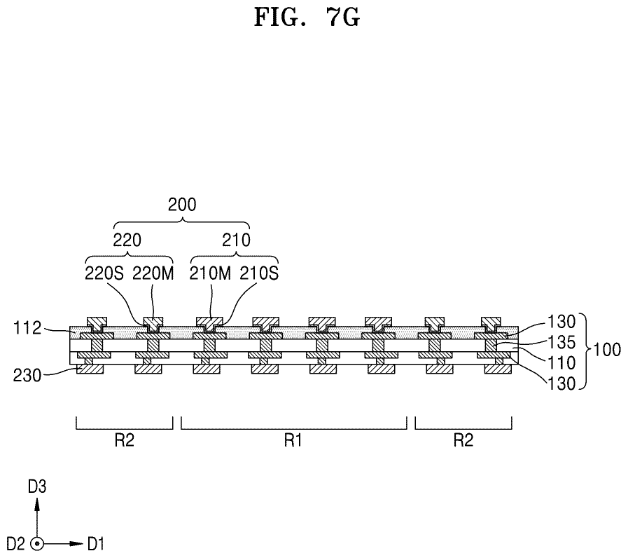

FIGS. 7A to 7G diagrams illustrating a method of manufacturing a substrate, according to some embodiments of the present disclosure.

Referring to FIG. 7A, the base substrate 100 may be first prepared. In an embodiment, the base substrate 100 may include forming the conductive vias 135 in the insulating layers 110 and forming the wiring patterns 130 on the insulating layers 110. The lower pads 230 may be further formed on a lower surface of the lowermost insulating layer 110. In an embodiment, forming the lower pads 230 may be performed after forming the conductive pads 200, as described below with reference to FIG. 7G.

The protective layer 112 may be formed on an upper surface of the base substrate 100 to cover the uppermost wiring pattern 130 and the uppermost insulating layer 110. In an embodiment, the forming of the protective layer 112 may include coating a solder resist material.

Referring to FIG. 7B, an exposure process and a development process may be performed on the protective layer 112 to form holes 119 in the protective layer 112. In an embodiment, the holes 119 may expose a portion of the upper surface of the wiring patterns 130. After the holes 119 are formed, a curing process of the protective layer 112 may be further performed.

Referring to FIG. 7C, a seed layer 200S may be formed within the holes 119 and on an upper surface of the protective layer 112. The seed layer 200S may conformally cover upper and inner walls of the protective layer 112 and the exposed portions of the upper surfaces of the wiring patterns 130. The seed layer 200S may include a conductive seed material. In an embodiment, the seed layer 200S may be formed by a deposition process.

Referring to FIG. 7D, a solder resist pattern 900 may be formed on an upper surface of the seed layer 200S. In an embodiment, the forming of the solder resist pattern 900 may be performed by a coating process. The solder resist pattern 900 may include a solder resist material.

In an embodiment, a first opening 910 and a second opening 920 may be formed within the solder resist pattern 900. The first opening 910 and the second opening 920 may be formed by the exposure process and the development process. The first and second openings 910 and 920 may be spatially connected to the corresponding holes 119, respectively. The first and second openings 910 and 920 may expose first portions of the seed layer 200S.

The first opening 910 may be formed on the center region R1 of the base substrate 100. In an embodiment, the first opening 910 may have a circular or oval planar shape. The second opening 920 may be formed on the corner regions R2 of the base substrate 100. The second opening 920 may have a different planar shape from that of the first opening 910. For example, the second opening 920 may have a polygonal planar shape.

After the first openings 910 and the second openings 920 are formed, a curing process of the solder resist pattern 900 may be further performed.

Referring to FIG. 7E, the first metal pad 210M and the second metal pad 220M may be formed in the first openings 910 and the second openings 920, respectively. In an embodiment, the first metal pad 210M and the second metal pad 220M may be formed by performing an electroplating process using the seed layer 200S as an electrode. In an embodiment, the electroplating process may be performed until an upper surface of the first metal pad 210M and an upper surface of the second metal pad 220M are provided at the same or lower level (e.g., in the third direction D3) as the upper surface of the solder resist pattern 900. Accordingly, the first metal pad 210M may be formed locally within the first openings 910, and the second metal pad 220M may be formed locally within the second opening 920. Accordingly, a planarization process of the first and second metal pads 210M and 220M may be omitted, and thus, a formation process of the first and second metal pads 210M and 220M may be simplified.

The planar shape of the upper surface of the first metal pad 210M may correspond to the planar shape of the first opening 910. The planar shape of the upper surface of the second metal pad 220M may correspond to the planar shape of the second opening 920.

Referring to FIG. 7F, the solder resist pattern 900 may be removed to expose an upper surface of a second portion of the seed layer 200S. The first portions of the seed layer 200S may be disposed on the lower surfaces of the first and second metal pads 210M and 220M.

Referring to FIGS. 7F and 7G in turn, the exposed second portion of the seed layer 200S may be removed to form the first seed pattern 210S and the second seed pattern 220S. In an embodiment, the removal of the second portion of the seed layer 200S may be performed by an etching process. For example, the etching process may be a wet etching process. In the etching process, the first and second metal pads 210M and 220M may have etch selectivity with respect to the seed layer 200S. The first portions of the seed layer 200S may be disposed on the lower surfaces of the first and second metal pads 210M and 220M and may not be exposed to the etching process. After the etching process is completed, the remaining first portions of the seed layer 200S may form the first seed pattern 210S and the second seed pattern 220S. The second seed pattern 220S may be separated from the first seed pattern 210S. Accordingly, the first conductive pads 210 and the second conductive pads 220 may be manufactured. Each of the first conductive pads 210 may include the first seed pattern 210S and the first metal pad 210M. The planar shape (e.g., in a plane defined in the first and second directions D1, D2) of each of the first conductive pads 210 may be the same as the planar shape (e.g., in a plane defined in the first and second directions D1, D2) of the upper surface of the first metal pad 210M. Each of the second conductive pads 220 may include the second seed pattern 220S and the second metal pad 220M. The planar shape (e.g., in a plane defined in the first and second directions D1, D2) of each of the second conductive pads 220 may be the same as the planar shape (e.g., in a plane defined in the first and second directions D1, D2) of the upper surface of the second metal pad 220M. Accordingly, manufacturing of the substrate may be completed.

According to an embodiment of the present disclosure, first conductive pads may be disposed on a center region of a base substrate. Second conductive pads may be disposed on corner regions of the base substrate and may have different planar shapes from those of the first conductive pads. The arrangement and planar shapes of the second conductive pads may be controlled to ensure a minimum space between the second conductive pads. In a process of bonding solder balls to the second conductive pads, an electrical short between the solder balls may be prevented. The manufacturing yield of a semiconductor module may be increased, and the reliability of semiconductor module may be increased.

While the present disclosure have been particularly shown and described with reference to non-limiting embodiments thereof, it will be understood that various changes in form and details may be made from the described embodiments without departing from the spirit and scope of the present disclosure.

What is claimed is:

1. A substrate comprising:
a base substrate comprising a center region and a corner region in a plan view, the base substrate comprising wiring patterns and an insulating layer;
first conductive pads on an upper surface of the center region of the base substrate; and
second conductive pads on an upper surface of the corner region of the base substrate,
wherein each of the first conductive pads has a circular or oval shape in the plan view, and
wherein each of the second conductive pads has a polygonal shape in the plan view.

2. The substrate of claim 1, wherein a minimum space between adjacent second conductive pads is greater than a minimum space between adjacent first conductive pads.

3. The substrate of claim 2, wherein a maximum width of each of the second conductive pads is in a range of about 95% to about 105% of a maximum diameter of each of the first conductive pads.

4. The substrate of claim 1, wherein the corner region of the base substrate is adjacent to a corner where first and second side surfaces of the base substrate meet in the plan view.

5. The substrate of claim 4, wherein:
the second conductive pads are disposed in the corner region of the base substrate and are arranged in rows extending in a first direction in the plan view;
a number of the second conductive pads in an (a+1) row is less than a number of the second conductive pads in an (a) row, wherein (a) is a natural number greater than or equal to 1;
the second conductive pads in the (a) row are disposed between the first side surface of the base substrate and the second conductive pads in the (a+1) row; and
the first side surface of the base substrate extends in the first direction.

6. The substrate of claim 5, wherein:
the second conductive pads are arranged in columns extending in a second direction in the plan view, the second direction crossing the first direction;
a number of the second conductive pads in a (b+1) column is less than a number of the second conductive pads in a (b) column, wherein (b) is a natural number greater than or equal to 1;
the second conductive pads in the (b) column are disposed between a second side surface of the base substrate and the second conductive pads in the (b+1) column; and
the second side surface of the base substrate extends in the second direction.

7. The substrate of claim 1, wherein each of the second conductive pads has a rectangular shape in the plan view.

8. The substrate of claim 1, wherein each of the second conductive pads has a hexagonal shape in the plan view.

9. A substrate comprising:
a base substrate comprising a center region and a corner region in a plan view;
first conductive pads on an upper surface of the center region of the base substrate; and
second conductive pads on an upper surface of the corner region of the base substrate,
wherein each of the second conductive pads has a polygonal shape in the plan view,
each of the first conductive pads has a different shape in the plan view than the polygonal shape of the second conductive pads in the plan view,
the second conductive pads are arranged in rows extending in a first direction in the plan view,
a number of the second conductive pads in an (a+1) row is less than a number of the second conductive pads in a first row, wherein (a) is a natural number greater than or equal to 1, and
the second conductive pads in the first row are disposed between a first side surface of the base substrate and the second conductive pads in the (a+1) row.

10. The substrate of claim 9, wherein a minimum space between adjacent second conductive pads is greater than a minimum space between adjacent first conductive pads.

11. The substrate of claim 9, wherein:
the second conductive pads are arranged in columns extending in a second direction in the plan view, the second direction crossing the first direction;
a number of the second conductive pads in a (b+1) column is less than a number of the second conductive pads in a first column, wherein (b) is a natural number greater than or equal to 1; and
the second conductive pads in the first column are disposed between a second side surface of the base substrate and the second conductive pads in the (b+1) column.

12. The substrate of claim 11, wherein:
the corner region of the base substrate is adjacent to a corner where the first side surface and the second side surface of the base substrate meet in the plan view;
the first side surface of the base substrate extends in the first direction; and
the second side surface of the base substrate extends in the second direction.

13. The substrate of claim 11, wherein a maximum space between the second side surface of the base substrate and a last column of the second conductive pads is in a range of about 15% to about 20% of a length of the first side surface of the base substrate.

14. The substrate of claim 9, wherein:
the second conductive pads are arranged in columns in the plan view, the second conductive pads in a first column are aligned in a second direction, the second direction crossing the first direction, and
the second conductive pads each have a quadrangular shape in the plan view, and vertices of the quadrangular shape of the second conductive pads face directions different from the first direction and the second direction.

15. The substrate of claim 9, wherein:
the second conductive pads in the (a+1) row are arranged offset from the second conductive pads in an (a) row in the first direction in the plan view; and
each of the second conductive pads has a quadrangular shape, and at least one of vertices of the quadrangular shape of the second conductive pads faces the first direction.

16. The substrate of claim 9, wherein:
a maximum space between the first side surface of the base substrate and a last row of the second conductive pads is in a range of about 15% to about 20% of a length of a second side surface of the base substrate; and
the second side surface of the base substrate is adjacent to the first side surface.

17. The substrate of claim 9, wherein:
the first conductive pads each have a circular or oval shape in the plan view; and
the second conductive pads each have a quadrangular or octagonal shape in the plan view.

18. A semiconductor module comprising:
a module substrate; and
a semiconductor package disposed on an upper surface of the module substrate,
wherein the module substrate comprises:
a base substrate comprising a center region and corner regions in a plan view, the base substrate comprising wiring patterns and an insulating layer; and
conductive pads disposed on an upper surface of the base substrate, the conductive pads are electrically connected to the wiring patterns,
wherein each of the conductive pads comprises a seed pattern and a metal pad on the seed pattern, and the seed pattern is disposed between the metal pad and a corresponding one of the wiring patterns,
wherein the conductive pads comprise:
first conductive pads disposed on an upper surface of the center region of the base substrate, each of the first conductive pads having a circular or oval shape in the plan view; and
second conductive pads disposed on upper surfaces of the corner regions of the base substrate, each of the second conductive pads having a polygonal shape in the plan view,
wherein the semiconductor package comprises:
a package substrate;
a semiconductor chip mounted on an upper surface of the package substrate;
a molding layer disposed on the upper surface of the package substrate, the molding layer covering the semiconductor chip; and
solder balls disposed on a lower surface of the package substrate,
wherein the solder balls are connected to the conductive pads.

19. The semiconductor module of claim 18, wherein:
the second conductive pads are arranged in rows extending in a first direction and columns arranged in a second direction crossing the first direction;
a number of the second conductive pads in an (a+1) row is less than a number of the second conductive pads in a first row, wherein (a) is a natural number greater than or equal to 1;
the second conductive pads in the first row are disposed between a first side surface of the base substrate and the second conductive pads in the (a+1) row;
a number of the second conductive pads in a (b+1) column is less than a number of the second conductive pads in a first column, wherein (b) is a natural number greater than or equal to 1; and
the second conductive pads in the first column are disposed between a second side surface of the base substrate and the second conductive pads in the (b+1) column.

20. The semiconductor module of claim 18, further comprising:
a protective layer covering the wiring patterns, wherein the protective layer includes:
openings exposing the wiring patterns; and
the conductive pads are disposed within the openings.
